(19) United States
(12) Patent Application Publication
(10) Pub. No.: US 2026/0298560 A1
(43) Pub. Date: Oct. 1, 2026

(54) INTERNAL LIMITED DIRECTION MANIFOLD

(71) Applicant: Delta Electronics, Inc., Taoyuan City (TW)

(72) Inventors: Mu-Bo Chang, Taoyuan City (TW); Hung-Min Cho, Taoyuan City (TW); Yu-Fan Yang, Taoyuan City (TW); Kuan-Lung Wu, Taoyuan City (TW)

(21) Appl. No.: 19/533,199

(22) Filed: Feb. 8, 2026

Related U.S. Application Data
(60) Provisional application No. 63/777,893, filed on Mar. 26, 2025.

(30) Foreign Application Priority Data
Jun. 12, 2025 (TW) 114206023

(51) Int. Cl. F28F 9/02

(52) U.S. Cl. CPC F28F 9/0256

(57) ABSTRACT

An internal limited direction manifold is disclosed and includes a manifold body, plural inlet fittings, plural check valves and an outlet fitting. The manifold body includes a first lateral side, a second lateral side and an inner space. The manifold body is extended along a first direction, and the first lateral side and the second lateral side are arranged opposite to each other in a second direction perpendicular to the first direction. The inlet fittings are disposed on the first lateral side. The check valves are accommodated within the inner space. Each check valve is correspondingly connected to the of inlet fitting, and allows a coolant to flow through the inlet fitting in a single direction into the inner space. The outlet fitting is disposed on the second lateral side of the manifold body and in communication with the inner space, to guide the coolant out of the inner space.

### CROSS-REFERENCE TO RELATED APPLICATION

This application claims the benefit of U.S. Provisional Application No. 63/777,893 filed on Mar. 26, 2025, and entitled “INTERNAL LIMITED DIRECTION MANIFOLD”. This application claims priority to Taiwan Patent Application No. 114206023, filed on Jun. 12, 2025. The entireties of the above-mentioned patent applications are incorporated herein by reference for all purposes.

### FIELD OF THE INVENTION

The present disclosure relates to a manifold structure, and more particularly to an internal limited direction manifold, having a check valve combined with an inlet fitting and embedded in an inner space of a manifold body by welding, thereby decreasing the risk of liquid leakage, and providing functions of preventing liquid backflow, protecting parts, and evenly controlling the flow rate at the same time.

### BACKGROUND OF THE INVENTION

A manifold, a liquid collection or distribution unit, is well known in liquid cooling product or IT server rack. It's a common component with several different inlet and outlet in a closed pipe system, usually set in a loop to combine multiple different flow to a single main flow or also in a revise operation to distribute a single source to multiple different output.

In the prior art, a manifold is designed with several fittings in different sides to fulfill distribution function. If the flow loop is required with more functional application, such as directional limitation, open/close loop or hot swap, we need to install more valve, fitting or adapter which require additional components and space. On the other hand, one additional joint fitting creates one risk of leakage and one assemble process.

Therefore, there is a need of providing an internal limited direction manifold, having a check valve combined with an inlet fitting and embedded in an inner space of a manifold body by welding, so as to decrease the risk of liquid leakage, provide the functions of preventing liquid backflow, protecting parts, and evenly controlling the flow rate at the same time, and obviate the drawbacks encountered by the prior arts.

### SUMMARY OF THE INVENTION

An object of the present disclosure is to provide an internal limited direction manifold, having a check valve combined with an inlet fitting and embedded in an inner space of a manifold body by welding, so as to decrease the risk of liquid leakage, and provide the functions of preventing liquid backflow, protecting parts, and evenly controlling the flow rate at the same time.

Another object of the present disclosure is to provide an internal limited direction manifold. The structure of the internal limited direction manifold in the present disclosure can be formed by pre-assembling the inlet assembly of the check valve and the inlet fitting, and then installing the inlet fitting to the manifold body through the welding process. The check valves of the plurality of inlet assemblies control the coolant to flow into the inner space of the manifold body in a single direction. After filling the inner space, the coolant is discharged through the outlet fitting, and the coolant is prohibited from flowing back from the inner space to the plurality of inlet fitting. The plurality of inlet fittings and the outlet fitting are connected to the manifold body by welding, so as to avoid the leakage problems that may occur due to additional disassembly and assembly. The check valve is embedded in the manifold body to control the inflow direction, and it helps the coolant circulation system to achieve multiple applications in a limited space. The check valve can be any type of valve suitable for embedding into the manifold body. In case of that the plurality of inlet fittings are arranged on one single side of the square tube, each inlet fitting with the check valve allows a water pump to be connected thereto, and the coolant is continuously pumped to the outlet fitting arranged on the other single side. The internal limited direction manifold of the present disclosure only allows the coolant to flow into the manifold body in a single direction, so that the water pump connected to each inlet fitting can be operated in different working modes, such as delivering the coolant into the inner space of the manifold body with different flow rates. In addition, when any one of the water pumps stops operating or is disassembled for maintenance, the protection mechanism formed by the internal limited direction manifold allows the other remaining water pumps to continue operating to guide the coolant into the inner space of the manifold body. The coolant in the inner space will not flow back into the idle or other water pumps, and the damage is avoided. Compared with the conventional manifolds that control pipelines through external accessories, the internal limited direction manifold of the present disclosure can protect the connected parts without adding any additional accessories, and the space requirements are greatly reduced. Furthermore, when the liquid sources introduced through the plurality of inlet fittings are unbalanced, the internal limited direction manifold can also be operated normally. After filling the inner space of the manifold body, the coolant is discharged through the outlet fitting, and the flow control function is effectively exerted. On the other hand, all of the inlet fittings and the outlet fitting are connected to the manifold body by welding process, so that the number of joints in the entire piping system is reduced, thereby reducing the risk of liquid leakage. Certainly, the present disclosure is not limited thereto.

In accordance with an aspect of the present disclosure, an internal limited direction manifold is provided and includes a manifold body, a plurality of inlet fittings, a plurality of check valves and at least one outlet fitting. The manifold body includes a first lateral side, a second lateral side and an inner space, wherein the manifold body is extended along a first direction, the inner space is formed between the first lateral side and the second lateral side, and the first lateral side and the second lateral side are arranged opposite to each other in a second direction, wherein the first direction is perpendicular to the second direction. The plurality of inlet fittings are disposed on the first lateral side. The plurality of check valves are accommodated within the inner space, wherein each of the plurality of check valves is correspondingly connected to the plurality of inlet fittings, respectively, wherein each of the plurality of check valves allows a coolant to flow through a corresponding one of the plurality of inlet fittings in a single direction into the inner space. The at least one outlet fitting is disposed on the second lateral side of the manifold body and in communication with the inner space, to guide the coolant out of the inner space.

In an embodiment, each of the plurality of inlet fittings includes a mounting surface, and an outer periphery of the mounting surface is connected to the first lateral side by welding.

In an embodiment, the plurality of check valves are respectively connected to the mounting surfaces of the plurality of inlet fittings.

In an embodiment, the manifold body includes a plurality of mounting holes, and the plurality of mounting holes penetrate the first lateral side, wherein the plurality of inlet fittings are arranged on the first lateral side, and each of the plurality of check valves is accommodated in the inner space of the manifold body through a corresponding one of the plurality of mounting holes, respectively.

In an embodiment, an outer diameter of the plurality of inlet fittings is greater than a diameter of the plurality of mounting holes, and the diameter of the plurality of mounting holes is greater than or equal to an outer diameter of the plurality of check valves.

In an embodiment, each of the plurality of inlet fittings is connected to a water pump, respectively, wherein the water pump is operated, the coolant flows into the manifold body through the plurality of inlet fittings in the single direction.

In an embodiment, when one of the plurality of water pumps stops operating, the remaining plurality of water pumps are allowed to maintain operation to introduce the coolant into the inner space of the manifold body.

In an embodiment, each of the plurality of water pumps is allowed to maintain operation with different flow rates of the coolant into the inner space of the manifold body.

In an embodiment, the coolant is discharged through the at least one outlet fitting after filling the inner space of the manifold body.

In an embodiment, the plurality of inlet fittings are arranged at equal intervals and disposed on the first lateral side of the manifold body, and the at least one outlet fitting is disposed at one end of the second lateral side of the manifold body.

In an embodiment, the at least one outlet fitting is fixed to the second lateral side of the manifold body by welding.

In an embodiment, each of the plurality of check valves prohibits the coolant from flowing back from the inner space to the plurality of inlet fittings.

In an embodiment, the plurality of check valves and the plurality of inlet fittings are assembled respectively and then installed to the first lateral side of the manifold body.

In an embodiment, a spaced distance is formed between the first lateral side and the second lateral side, and the plurality of check valves protrude from the first lateral side toward the inner space to form a protrusion distance, wherein the protrusion distance is less than one third of the spaced distance.

In an embodiment, the manifold body is composed of a tubular structure.

In an embodiment, each of the plurality of inlet fittings includes a coupling end connected to an input conduit element via a detachable clamp.

In an embodiment, the plurality of inlet fittings and the at least one outlet fitting are misaligned in view of the second direction.

In accordance with another aspect of the present disclosure, an internal limited direction manifold is provided and includes a manifold body, a plurality of inlet fittings, a plurality of check valves and at least one outlet fitting. The manifold body includes a first lateral side, a second lateral side and an inner space, wherein the manifold body is extended along a first direction, the inner space is formed between the first lateral side and the second lateral side, and the first lateral side and the second lateral side are arranged opposite to each other in a second direction, wherein the first direction is perpendicular to the second direction. The plurality of inlet fittings are disposed on the first lateral side. The plurality of check valves are accommodated within the inner space, wherein each of the plurality of check valves is correspondingly connected to the plurality of inlet fittings, respectively, wherein each of the plurality of check valves allows a coolant to flow through a corresponding one of the plurality of inlet fittings in a single direction into the inner space. The at least one outlet fitting is disposed on the first lateral side of the manifold body and in communication with the inner space, to guide the coolant out of the inner space.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a perspective structural view illustrating an internal limited direction manifold according to a first embodiment of the present disclosure;

FIG. 2 is an exploded view illustrating the internal limited direction manifold according to the first embodiment of the present disclosure;

FIG. 3 is a horizontal cross-sectional view illustrating the internal limited direction manifold according to the first embodiment of the present disclosure;

FIG. 4 is a perspective structural view illustrating the application of the internal limited direction manifold connected to a plurality of water pumps according to the first embodiment of the present disclosure;

FIG. 5 is a top view illustrating a usage status of the internal limited direction manifold in FIG. 4;

FIG. 6 is a schematic diagram showing another usage state of the internal limited direction manifold in FIG. 4;

FIG. 7 is a schematic diagram showing a further usage state of the internal limited direction manifold in FIG. 4;

FIG. 8 is a perspective structural view illustrating an internal limited direction manifold according to a second embodiment of the present disclosure;

FIG. 9 is an exploded view illustrating the internal limited direction manifold according to the second embodiment of the present disclosure; and

FIG. 10 is a perspective structural view illustrating the application of the internal limited direction manifold connected to a plurality of water pumps according to the second embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “front,” “rear,” “top,” “bottom,” “inner,” “outer,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items.

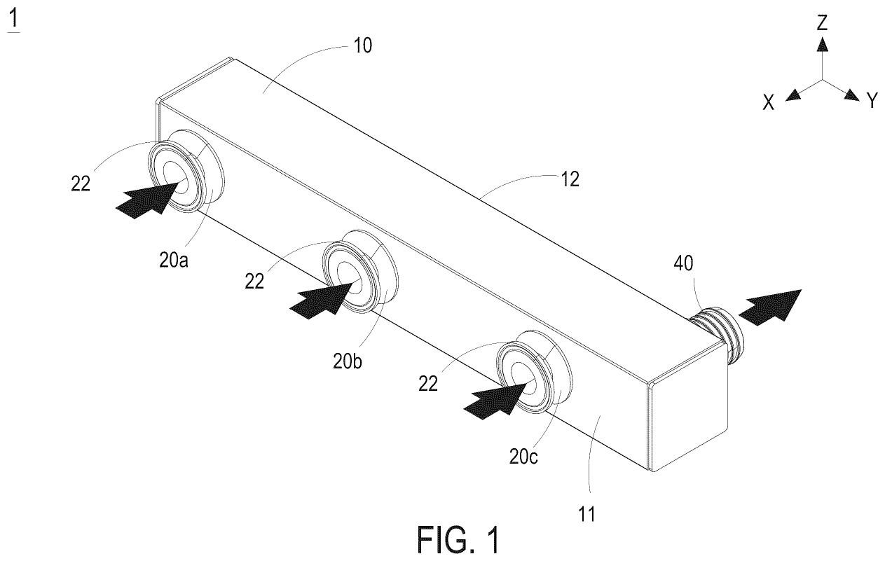

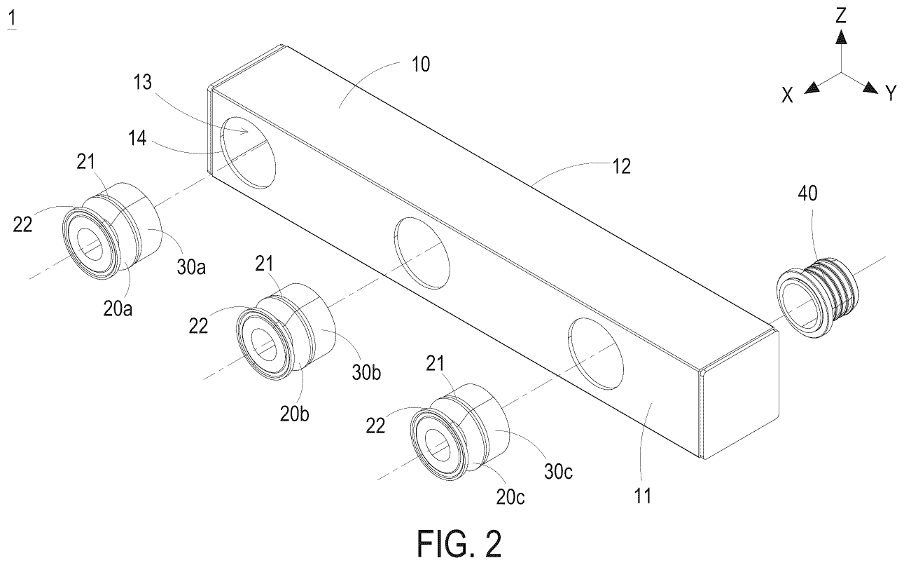

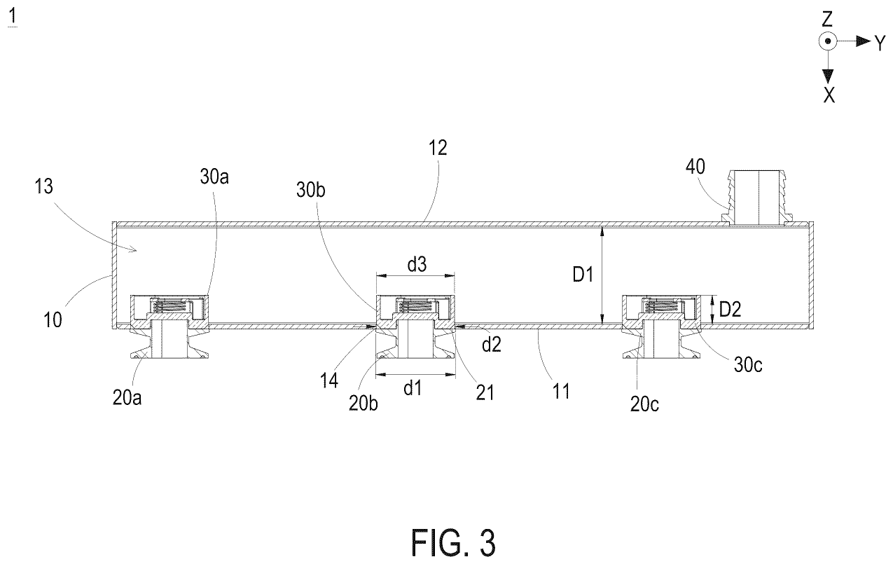

FIG. 1 is a perspective structural view illustrating an internal limited direction manifold according to a first embodiment of the present disclosure. FIG. 2 is an exploded view illustrating the internal limited direction manifold according to the first embodiment of the present disclosure. FIG. 3 is a horizontal cross-sectional view illustrating the internal limited direction manifold according to the first embodiment of the present disclosure. The present disclosure provides an internal limited direction manifold 1, which includes a manifold body 10, a plurality of inlet fittings 20a, 20b, 20c, a plurality of check valves 30a, 30b, 30c and at least one outlet fitting 40. The manifold body 10 includes a first lateral side 11, a second lateral side 12 and an inner space 13. Preferably but not exclusively, the manifold body 10 is composed of a tubular structure such as a 70 mm diameter square tube, and extended along a first direction such as the Y axial direction. Moreover, the left end and the right end are sealed with cover plates, so that the inner space 13 is formed between the first lateral side 11 and the second lateral side 12, and the first lateral side 11 and the second lateral side 12 are arranged opposite to each other in a second direction, such as the reverse X axial direction. Preferably but not exclusively, the first lateral side 11 and the second lateral side 12 are front lateral side and the rear lateral side of the manifold body 10. In the embodiment, the first direction (i.e., the Y axial direction) is perpendicular to the second direction (i.e., the reverse X axial direction). The plurality of inlet fittings 20a, 20b, 20c are disposed on the first lateral side 11 of the manifold body 10. The plurality of check valves 30a, 30b, 30c are accommodated within the inner space 13 of the manifold body 10. Moreover, each of the plurality of check valves 30a, 30b, 30c is correspondingly connected to the plurality of inlet fittings 20a, 20b, 20c, respectively. In the embodiment, each of the plurality of check valves 30a, 30b, 30c allows a coolant (not shown) to flow through a corresponding one of the plurality of inlet fittings 20a, 20b, 20c in a single direction, such as the reverse X axial direction, into the inner space 13 of the manifold body 10. In other words, each of the plurality of check valves 30a, 30b, 30c prohibits the coolant from flowing back from the inner space 13 of the manifold body 10 to the plurality of inlet fittings 20a, 20b, 20c. In the embodiment, the at least one outlet fitting 40 is disposed on the second lateral side 12 of the manifold body 10 and in communication with the inner space 13, to guide the coolant out of the inner space 13. After filling the inner space 13 of the manifold body 10, the coolant is discharged through the at least one outlet fitting 40. Preferably but not exclusively, in other embodiments, the at l east one outlet fitting 40 is disposed on the top side, the bottom side, the left end or the right end of the manifold body 10. The direction in which the coolant is led out of the inner space 13 is not an essential technical feature of the present disclosure.

Notably, in the embodiment, the plurality of check valves 30a, 30b, 30c and the plurality of inlet fittings 20a, 20b, 20c are assembled into one piece, respectively and then installed to the first lateral side 11 of the manifold body 10. In the embodiment, each of the plurality of inlet fittings 20a, 20b, 20c includes a mounting surface 21, and an outer periphery of the mounting surface 21 is connected to the first lateral side 11 of the manifold body 10 by welding. In addition, when the plurality of check valves 30a, 30b, 30c and the plurality of inlet fittings 20a, 20b, 20c are pre-assembled into the integrated structures, respectively. The plurality of check valves 30a, 30b, 30c are respectively connected to an inner periphery of the mounting surface 21 of the plurality of inlet fittings 20a, 20b, 20c, and can be partially fitted and connected. Certainly, the assembling method of the two elements is not an essential technical feature to limit the present disclosure. In the embodiment, the manifold body 10 includes a plurality of mounting holes 14. The plurality of mounting holes 14 penetrate the first lateral side 11. Preferably but not exclusively, the plurality of inlet fittings 20a, 20b, 20c (including the corresponding check values 30a, 30b, 30c) are arranged on the first lateral side 11 of the manifold body 10, and each of the plurality of check valves 30a, 30b, 30c is accommodated in the inner space 13 of the manifold body 10 through a corresponding one of the plurality of mounting holes 14, respectively. Then, the outer peripheries of the mounting surfaces 21 and the first lateral side 11 are welded.

In the embodiment, an outer diameter d1 of the plurality of inlet fittings 20a, 20b, 20c is greater than a diameter d2 of the plurality of mounting holes 14, and the diameter d2 of the plurality of mounting holes 14 is greater than or equal to an outer diameter d3 of the plurality of check valves 30a, 30b, 30c. In this way, the plurality of inlet fittings 20a, 20b, 20c (including the corresponding check valves 30a, 30b, 30c) are fixed to the first lateral side 11 of the manifold body 10 by welding, so as to form the structure of the internal limited direction manifold 1 of the present disclosure. Thereby, the check valves 30a, 30b, 30c are embedded in the inner space 13 of the manifold body 10 and provide the function of flow direction restriction. In the embodiment, the check valves 30a, 30b, 30c control the coolant to flow into the inner space 13 of the manifold body 10 only in one single direction (i.e., the reverse X axial direction). After filling the inner space 13, the coolant is discharged through the outlet fitting 40. The coolant is prohibited from flowing back from the inner space 13 to the plurality of inlet fittings 20a, 20b, 20c. In the embodiment, the plurality of inlet fittings 20a, 20b, 20c and the outlet fitting 40 are connected to the manifold body 10 by welding, so as to avoid the leakage problem that may occur due to additional disassembly and assembly. In addition, the check valves 30a, 30b, 30c are embedded in the manifold body 10 to control the inflow direction, and it helps the coolant circulation system to achieve multiple applications in a limited space. This will be further explained later.

In the embodiment, the coolant further fills the inner space 13 of the manifold body 10 and then is discharged through the at least one outlet fitting 40, so as to exert the flow converging function of the internal limited direction manifold 1. Preferably but not exclusively, the plurality of inlet fittings 20a, 20b, 20c (including the corresponding check valves 30a, 30b, 30c) are arranged at equal intervals and disposed on the first lateral side 11 of the manifold body 10. Moreover, the at least one outlet fitting 40 is disposed at one end of the second lateral side 12 of the manifold body 10. Furthermore, the plurality of inlet fittings 20a, 20b, 20c and the at least one outlet fitting 40 are misaligned in view of the second direction (i.e., the reverse X direction). In that, after the coolant is introduced into the inner space 13 of the manifold body 10 through the inlet fittings 20a, 20b, 20c in one single direction (i.e., the reverse X axial direction), there is enough time for the coolant to fill the inner space 13 of the manifold body 10. Finally, the coolant is discharged through the at least one outlet fit 40 in the revere X axial direction.

On the other hand, in the embodiment, a spaced distance D1 is formed between the first lateral side 11 and the second lateral side 12, and the plurality of check valves 30a, 30b, 30c protrude from the first lateral side 11 toward the inner space 13 to form a protrusion distance D2. In the embodiment, the plurality of check valves 30a, 30b, 30c and the plurality of inlet fittings 20a, 20b, 20c are respectively assembled into one piece and then mounted to the first lateral side 11 of the manifold body 10 through the mounting holes 14 on the first lateral side 11. Therefore, the protrusion distance D2 needs to be less than the spaced distance D1, so that the outer periphery of the mounting surface 21 of the inlet fittings 20a, 20b, 20c can be connected to the first lateral side 11 of the manifold body 10 by welding. In addition, the protrusion distance D2 is, for example, less than half of the spaced distance D1, so as to maintain the circulation of the coolant in the inner space 13. Preferably but not exclusively, the protrusion distance D2 is less than one third of the spaced distance D1. Thus, the embedded arrangement of the plurality of check valves 30a, 30b, 30c is helpful providing the function of controlling the inflow direction without affecting the flow confluence function of the inner space 13. Certainly, in other embodiments, the number, the size, the type and the arrangement position of the outlet fitting 40, the inlet fittings 20a, 20b, 20c and the check valves 30a, 30b, 30c are adjustable according to the practical requirements. The present disclosure is not limited thereto.

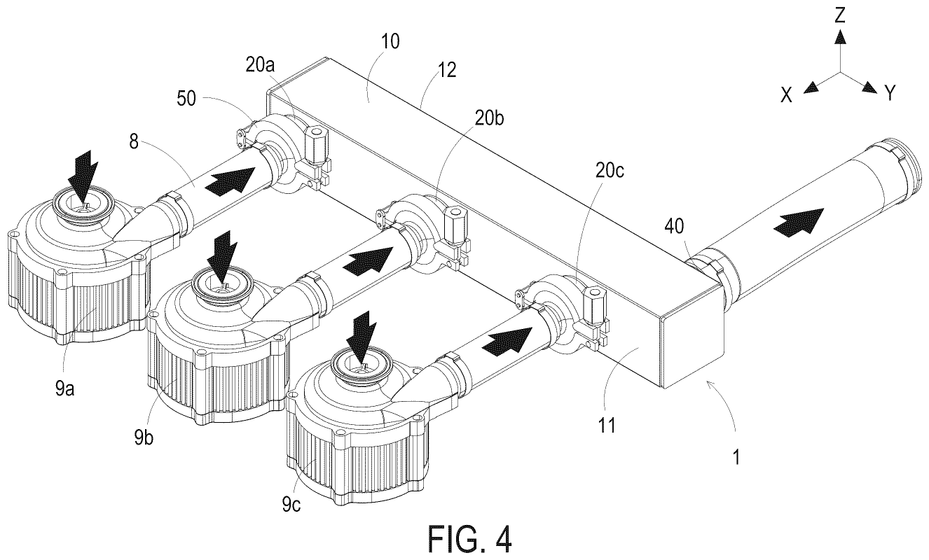

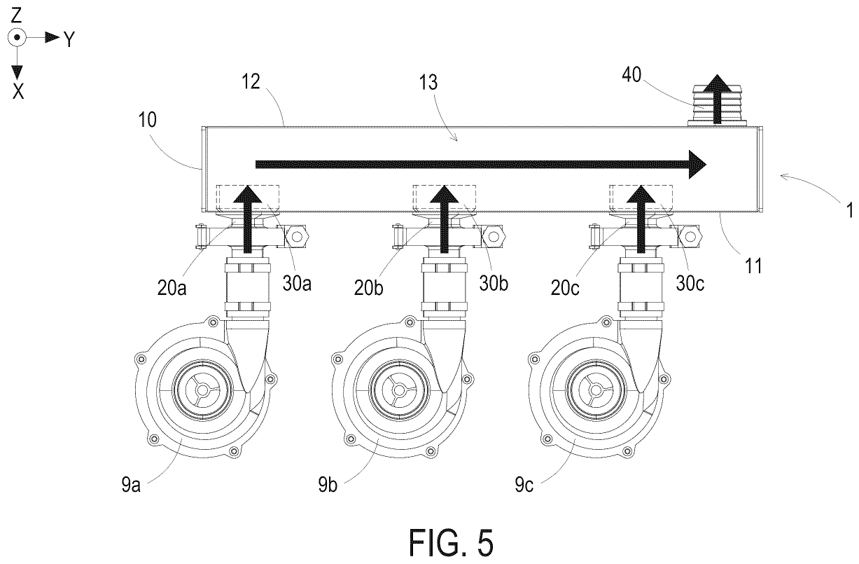

FIG. 4 is a perspective structural view illustrating the application of the internal limited direction manifold connected to a plurality of water pumps according to the first embodiment of the present disclosure. FIG. 5 is a top view illustrating a usage status of the internal limited direction manifold in FIG. 4. Please refer to FIG. 1 to FIG. 5. In the embodiment, the plurality of inlet fittings 20a, 20b, 20c are arranged at equal intervals in the first direction (i.e., the Y axial direction) and disposed on the first lateral side 11 of the manifold body 10. Furthermore, it allows the plurality of inlet fittings 2a, 20b, 20c to be externally connected with the water pumps 9a, 9b, 9c, respectively. In the embodiment, the water pumps 9a, 9b, 9c have the same structure, and can be operated in multiple operation modes, but the present disclosure is not limited thereto. In the embodiment, each of the plurality of inlet fittings 20a, 20b, 20c includes a coupling end 22 connected to an input conduit element 8 via a detachable clamp 50, and further connected to the water pumps 9a, 9b, 9c, respectively. Certainly, the connection manner of the plurality of inlet fittings 20a, 20b, 20c and the water pumps 9a, 9b, 9c is not an essential technical feature, and the present disclosure is not limited thereto. Notably, the internal limited direction manifold 1 of the present disclosure only allows the coolant to flow into the manifold body 10 in one single direction, and the inlet fittings 20a, 20b, 20c with the corresponding check valves 30a, 30b, 30c only allow the water pumps 9a, 9b, 9c correspondingly connected to pump the coolant into the manifold body 10. When the water pumps 9a, 9b, 9c are operated, the coolant is continuously pumped into the inner space 13 of the manifold body 10 through the plurality of inlet fittings 20a, 20b, 20c in one single direction (i.e., the reverse X axial direction). After filling the inner space 13 of the manifold body 10, the coolant is discharged through the outlet fitting 40 on the second lateral side 12. In the embodiment, the coolant enters the inner space 13 of the manifold body 10 evenly through the plurality of inlet fittings 20a, 20b, 20c. The coolant in the inner space 13 will not flow back to the inlet fittings 20a, 20b, 20c and the water pumps 9a, 9b, 9c. Therefore, the operations of the water pumps 9a, 9b, 9c are independent and do not affect each other. In other embodiments, the water pumps 9a, 9b, 9c have different operating specifications, and the coolant will not flow back to the inlet fittings 20a, 20b, 20c and the water pumps 9a, 9b, 9c after entering the inner space 13 of the manifold body 10. Certainly, the application of the internal limited direction manifold 1 of the present disclosure is not limited thereto.

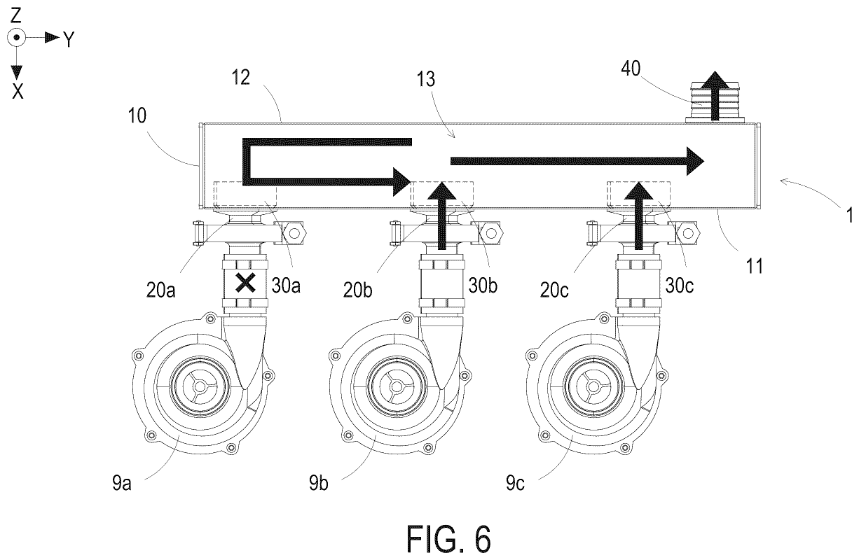

FIG. 6 is a schematic diagram showing another usage state of the internal limited direction manifold in FIG. 4. Please refer to FIG. 1 to FIG. 4 and FIG. 6. In the embodiment, when the water pump 9a stops operating, or is disassembled for maintenance, the other remaining water pumps 9b and 9c are allowed to maintain operation to continuously introduce the coolant into the inner space 13 of the manifold body 10. Through the protection mechanism formed by the internal limited direction manifold 1, the coolant already in the inner space 13 will not flow back into the water pump 9a that is stopped or disassembled for maintenance, so that the damage is avoided. In other words, in the other embodiments, when any one of the plurality of water pumps 9a, 9b, 9c stops operating, the remaining plurality of water pumps 9a, 9b, 9c are allowed to maintain operation to introduce the coolant into the inner space 13 of the manifold body 10 and provide the sufficient coolant to be discharged through the outlet fitting 40. In other words, when disassembling or maintaining some parts of the water pumps 9a, 9b, 9c, there is no need to stop the operation of the internal limited direction manifold 1. Certainly, the application scenarios of the internal limited direction manifold 1 of the present disclosure are not limited thereto.

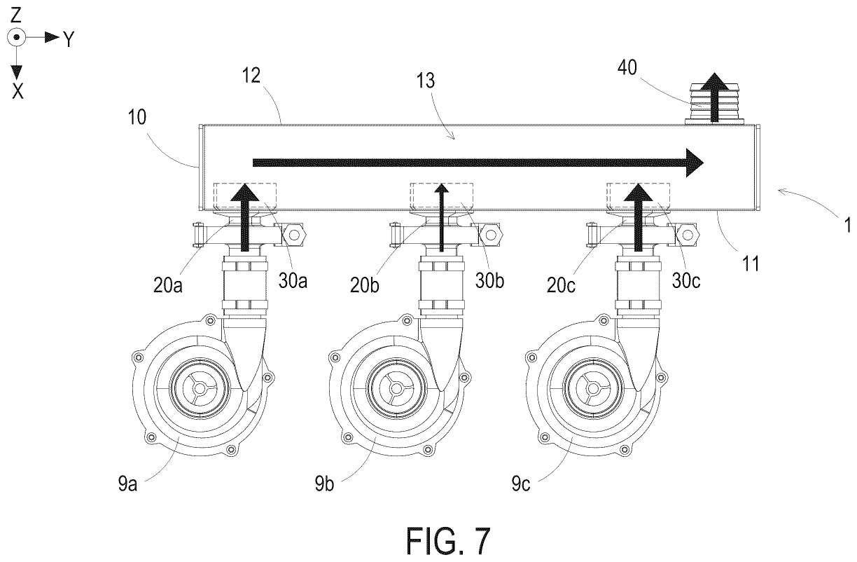

FIG. 7 is a schematic diagram showing a further usage state of the internal limited direction manifold in FIG. 4. Please refer to FIG. 1 to FIG. 4 and FIG. 7. In the embodiment, the water pumps 9a, 9c are operated at a normal flow rate to continuously introduce the coolant into the inner space 13 of the manifold body 10, while the water pump 9b is operated at a lower flow rate to continuously introduce the coolant into the inner space 13 of the manifold body 10. Since the internal limited direction manifold 1 of the present disclosure only allows the coolant to flow into the inner space 13 of the manifold body 10 in one single direction, each of the water pumps 9a, 9b, 9c connected correspondingly to the inlet fittings 20a, 20b, 20c can be operate at different working modes, such as, delivering the coolant into the inner space 13 of the manifold body 10 with different flow rates. In other embodiments, each of the plurality of water pumps 9a, 9b, 9c allows to maintain different operation with different flow rates of coolant into the inner space 13 of the manifold body 10. Certainly, the application scenarios of the internal limited direction manifold 1 of the present disclosure are not limited thereto.

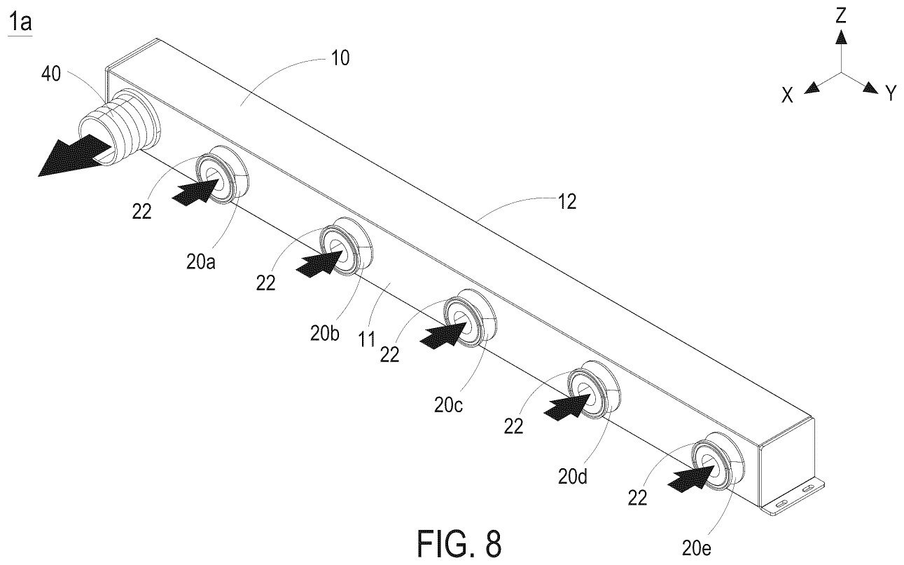

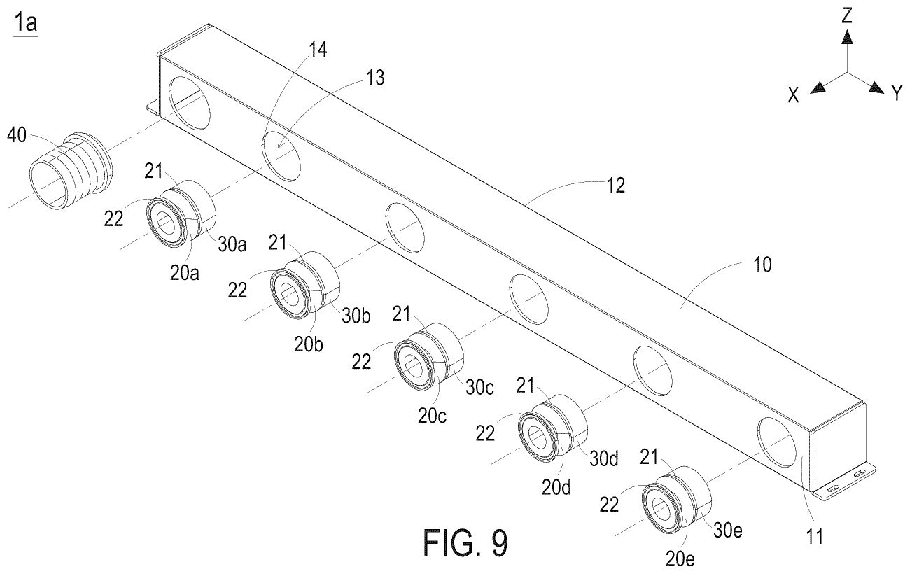

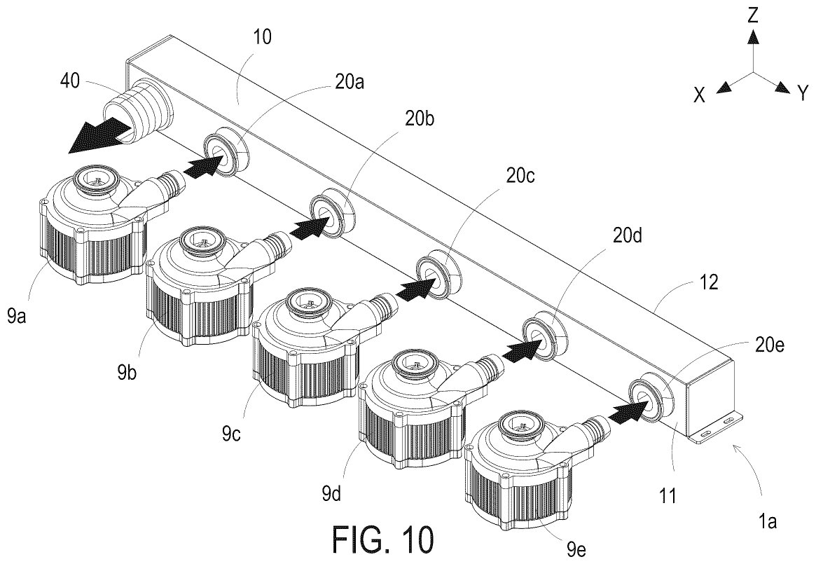

FIG. 8 is a perspective structural view illustrating an internal limited direction manifold according to a second embodiment of the present disclosure. FIG. 9 is an exploded view illustrating the internal limited direction manifold according to the second embodiment of the present disclosure. FIG. 10 is a perspective structural view illustrating the application of the internal limited direction manifold connected to a plurality of water pumps according to the second embodiment of the present disclosure. In the embodiment, the structures, elements and functions of the internal limited direction manifold 1a are similar to those of the internal limited direction manifold 1 in FIG. 1 to FIG. 7, and are not redundantly described herein. In the embodiment, the internal limited direction manifold 1a includes five inlet fittings 20a, 20b, 20c, 20d, 20e and five check valves 30a, 30b, 30c, 30d, 30e. Each of the five inlet fittings 20a, 20b, 20c, 20d, 20e includes a coupling end 22, which can be connected to the water pump 9a, 9b, 9c, 9d, 9e respectively in the above-mentioned manner. The water pumps 9a, 9b, 9c, 9d, 9e are operated independently and allowed to introduce the coolant into the manifold body 10 through the corresponding inlet fittings 20a, 20b, 20c, 20d, 20e and the corresponding check valves 30a, 30b, 30c, 30d, 30e. After entering the inner space 13 of the manifold body 10, the coolant will not flow back into the inlet fittings 20a, 20b, 20c, 20d, 20e and the water pumps 9a, 9b, 9c, 9d, 9e. Certainly, the application of the internal limited direction manifold 1a of the present disclosure is not limited thereto. Furthermore, in the embodiment, the at least one outlet fitting 40 is disposed on the first lateral side 11 of the manifold body 10 and in communication with the inner space 13. In other words, the outlet fitting 40 and the inlet fittings 20a, 20b, 20c, 20d, 20e are all disposed on the first lateral side 11. After the coolant enters the inner space 13 of the manifold body 10 through the inlet fittings 20a, 20b, 20c, 20d, 20e in one single direction (i.e., the reverse X axial direction), there is enough time for the coolant to fill the inner space 13 of the manifold body 10. Finally, the coolant is discharged through the at least one outlet fitting 40 in the X axial direction. Certainly, the present disclosure is not limited thereto.

Notably, the internal limited direction manifolds 1, 1a of the present disclosure combines the check valve with the welding installation of the inlet fitting so that the check valve is embedded in the inner space 13 of the manifold body 10, thereby preventing the liquid backflow and realizing the application of protecting parts. Compared with the conventional manifold that control the pipelines through external accessories, internal limited direction manifold of the present disclosure can protect the connected parts without adding any additional accessories, and the space requirements are greatly reduced. The inlet fittings 20a, 20b, 20c, 20d, 20e and the outlet fitting 40 are not limited to being arranged on the same lateral side or on two opposite sides. Furthermore, the inlet fittings 20a, 20b, 20c, 20d, 20e and the outlet fitting 40 are all connected to the manifold body 10 by welding, so that the number of joints in the entire pipeline system is reduced, thereby reducing the risk of liquid leakage. On the other hand, the application scenarios of the inlet fittings 20a, 20b, 20c, 20d, 20e externally connected to the input conduit elements 8 and the water pumps 9a, 9b, 9c, 9d, 9e can be adjusted according to the practical requirements. The present disclosure is not limited thereto and not redundantly described hereafter.

In summary, the present disclosure provides an internal limited direction manifold, having a check valve combined with an inlet fitting and embedded in an inner space of a manifold body by welding, so as to decrease the risk of liquid leakage, and provide the functions of preventing liquid backflow, protecting parts, and evenly controlling the flow rate at the same time. The structure of the internal limited direction manifold in the present disclosure can be formed by pre-assembling the inlet assembly of the check valve and the inlet fitting, and then installing the inlet fitting to the manifold body through the welding process. The check valves of the plurality of inlet assemblies control the coolant to flow into the inner space of the manifold body in a single direction. After filling the inner space, the coolant is discharged through the outlet fitting, and the coolant is prohibited from flowing back from the inner space to the plurality of inlet fitting. The plurality of inlet fittings and the outlet fitting are connected to the manifold body by welding, so as to avoid the leakage problems that may occur due to additional disassembly and assembly. The check valve is embedded in the manifold body to control the inflow direction, and it helps the coolant circulation system to achieve multiple applications in a limited space. The check valve can be any type of valve suitable for embedding into the manifold body. In case of that the plurality of inlet fittings are arranged on one single side of the square tube, each inlet fitting with the check valve allows a water pump to be connected thereto, and the coolant is continuously pumped to the outlet fitting arranged on the other single side. The internal limited direction manifold of the present disclosure only allows the coolant to flow into the manifold body in a single direction, so that the water pump connected to each inlet fitting can be operated in different working modes, such as delivering the coolant into the inner space of the manifold body with different flow rates. In addition, when any one of the water pumps stops operating or is disassembled for maintenance, the protection mechanism formed by the internal limited direction manifold allows the other remaining water pumps to continue operating to guide the coolant into the inner space of the manifold body. The coolant in the inner space will not flow back into the idle or other water pumps, and the damage is avoided. Compared with the conventional manifolds that control pipelines through external accessories, the internal limited direction manifold of the present disclosure can protect the connected parts without adding any additional accessories, and the space requirements are greatly reduced. Furthermore, when the liquid sources introduced through the plurality of inlet fittings are unbalanced, the internal limited direction manifold can also be operated normally. After filling the inner space of the manifold body, the coolant is discharged through the outlet fitting, and the flow control function is effectively exerted. On the other hand, all of the inlet fittings and the outlet fitting are connected to the manifold body by welding process, so that the number of joints in the entire piping system is reduced, thereby reducing the risk of liquid leakage. Certainly, the present disclosure is not limited thereto.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An internal limited direction manifold, comprising:
a manifold body comprising a first lateral side, a second lateral side and an inner space, wherein the manifold body is extended along a first direction, the inner space is formed between the first lateral side and the second lateral side, and the first lateral side and the second lateral side are arranged opposite to each other in a second direction, wherein the first direction is perpendicular to the second direction;
a plurality of inlet fittings disposed on the first lateral side;
a plurality of check valves accommodated within the inner space, wherein each of the plurality of check valves is correspondingly connected to the plurality of inlet fittings, respectively, wherein each of the plurality of check valves allows a coolant to flow through a corresponding one of the plurality of inlet fittings in a single direction into the inner space; and
at least one outlet fitting disposed on the second lateral side of the manifold body and in communication with the inner space, to guide the coolant out of the inner space.

2. The internal limited direction manifold according to claim 1, wherein each of the plurality of inlet fittings comprises a mounting surface, and an outer periphery of the mounting surface is connected to the first lateral side by welding.

3. The internal limited direction manifold according to claim 2, wherein the plurality of check valves are respectively connected to the mounting surfaces of the plurality of inlet fittings.

4. The internal limited direction manifold according to claim 3, wherein the manifold body comprises a plurality of mounting holes, and the plurality of mounting holes penetrate the first lateral side, wherein the plurality of inlet fittings are arranged on the first lateral side, and each of the plurality of check valves is accommodated in the inner space of the manifold body through a corresponding one of the plurality of mounting holes, respectively.

5. The internal limited direction manifold according to claim 4, wherein an outer diameter of the plurality of inlet fittings is greater than a diameter of the plurality of mounting holes, and the diameter of the plurality of mounting holes is greater than or equal to an outer diameter of the plurality of check valves.

6. The internal limited direction manifold according to claim 1, wherein each of the plurality of inlet fittings is connected to a plurality of water pumps, respectively, wherein the plurality of water pump are operated, the coolant flows into the manifold body through the plurality of inlet fittings in the single direction.

7. The internal limited direction manifold according to claim 6, wherein when one of the plurality of water pumps stops operating, the remaining plurality of water pumps are allowed to maintain operation to introduce the coolant into the inner space of the manifold body.

8. The internal limited direction manifold according to claim 6, wherein each of the plurality of water pumps is allowed to maintain operation with different flow rates of the coolant into the inner space of the manifold body.

9. The internal limited direction manifold according to claim 1, wherein the plurality of inlet fittings are arranged at equal intervals and disposed on the first lateral side of the manifold body, and the at least one outlet fitting is disposed at one end of the second lateral side of the manifold body.

10. The internal limited direction manifold according to claim 1, wherein the coolant is discharged through the at least one outlet fitting after filling the inner space of the manifold body.

11. The internal limited direction manifold according to claim 1, wherein the at least one outlet fitting is fixed to the second lateral side of the manifold body by welding.

12. The internal limited direction manifold according to claim 1, wherein each of the plurality of check valves prohibits the coolant from flowing back from the inner space to the plurality of inlet fittings.

13. The internal limited direction manifold according to claim 1, wherein the plurality of check valves and the plurality of inlet fittings are assembled respectively and then installed to the first lateral side of the manifold body.

14. The internal limited direction manifold according to claim 1, wherein a spaced distance is formed between the first lateral side and the second lateral side, and the plurality of check valves protrude from the first lateral side toward the inner space to form a protrusion distance, wherein the protrusion distance is less than one third of the spaced distance.

15. The internal limited direction manifold according to claim 1, wherein the manifold body is composed of a tubular structure.

16. The internal limited direction manifold according to claim 1, wherein each of the plurality of inlet fittings comprises a coupling end connected to an input conduit element via a detachable clamp.

17. The internal limited direction manifold according to claim 1, wherein the plurality of inlet fittings and the at least one outlet fitting are misaligned in view of the second direction.

18. An internal limited direction manifold, comprising:
a manifold body comprising a first lateral side, a second lateral side and an inner space, wherein the manifold body is extended along a first direction, the inner space is formed between the first lateral side and the second lateral side, and the first lateral side and the second lateral side are arranged opposite to each other in a second direction, wherein the first direction is perpendicular to the second direction;
a plurality of inlet fittings disposed on the first lateral side;
a plurality of check valves accommodated within the inner space, wherein each of the plurality of check valves is correspondingly connected to the plurality of inlet fittings, respectively, wherein each of the plurality of check valves allows a coolant to flow through a corresponding one of the plurality of inlet fittings in a single direction into the inner space; and
at least one outlet fitting disposed on the first lateral side of the manifold body and in communication with the inner space, to guide the coolant out of the inner space.

19. The internal limited direction manifold according to claim 18, wherein each of the plurality of inlet fittings is connected to a plurality of water pumps, respectively, wherein the plurality of water pumps are operated, the coolant flows into the manifold body through the plurality of inlet fittings in the single direction.

20. The internal limited direction manifold according to claim 19, wherein when one of the plurality of water pumps stops operating, the remaining plurality of water pumps are allowed to maintain operation to introduce the coolant into the inner space of the manifold body, wherein each of the plurality of water pumps is allowed to maintain operation with different flow rates of the coolant into the inner space of the manifold body.
